(19) United States
(12) Patent Application Publication
(10) Pub. No.: US 2012/0068343 A1
(43) Pub. Date: Mar. 22, 2012

(54) SEMICONDUCTOR DEVICE AND METHOD FOR MANUFACTURING THE SAME

(76) Inventors: Makoto Honda, Yokohama-Shi (JP); Masayuki Kitamura, Yokohama-Shi (JP)

(21) Appl. No.: 13/069,206

(22) Filed: Mar. 22, 2011

(30) Foreign Application Priority Data
Sep. 17, 2010 (JP) 2010-209745

(51) Int. Cl. H01L 23/48; H01L 21/768

(52) U.S. Cl. 257/751; 438/653; 257/E23.011; 257/E21.584

(57) ABSTRACT

According to one embodiment, a semiconductor device includes a semiconductor substrate, an interlayer dielectric film, a contact hole, a contact plug and a nickel silicide film. The semiconductor substrate includes silicon. The interlayer dielectric film is formed on the semiconductor substrate. The contact hole is formed in the interlayer dielectric film. A contact plug is formed within the contact hole. A nickel silicide film is formed on a bottom part of the contact hole and electrically connected to the contact plug. A position of an interface between the nickel silicide and the contact plug is higher than a position of an interface between the semiconductor substrate and the interlayer dielectric film.

### CROSS REFERENCE TO RELATED APPLICATIONS

This application is based upon and claims the benefit of priority from the prior Japanese Patent Application No. 2010-209745, filed on Sep. 17, 2010, the entire contents of which are incorporated herein by reference.

### FIELD

Embodiments described herein relate generally to a semiconductor device and method for manufacturing the same.

### BACKGROUND

Conventional a semiconductor device includes a contact plug surrounded by barrier metal on silicon, polysilicon, or silicide film. In the conventional semiconductor device, its contact resistance is reduced when titanium or titanium nitride as barrier metal reacts with silicon and titanium silicide (TiSi₂) is formed.

However, for example, in conjunction with shrinkage of the conventional semiconductor devices, it is difficult to form titanium silicide and to reduce the contact resistance due to the influence of defects in a silicon film, a diffusion layer, or diffusion species.

### BRIEF DESCRIPTION OF THE DRAWINGS

FIGS. 1A to 1G are main-part sectional views that show a manufacturing process of a semiconductor device of a first embodiment.

FIGS. 2A to 2C are main-part sectional views that show a manufacturing process of a semiconductor device of a second embodiment

FIG. 3 is a graph that compares orientations of the nickel silicide films formed by using the manufacturing methods of the first and second embodiments.

FIGS. 4A and 4B are main-part sectional views of first and second samples of the second embodiment.

FIG. 4C is a table that shows a sheet resistance (Q) of the first and second samples.

FIG. 4D is a graph that shows the relationship between a contact resistance and cumulative probability of the first and second samples.

FIGS. 5A to 5C are main-part sectional views that show a manufacturing process of a semiconductor device of a third embodiment

### DETAILED DESCRIPTION

Embodiments will now be explained with reference to the accompanying drawings.

### Summary of Embodiments

In general, according to one embodiment, a semiconductor device includes a semiconductor substrate, an interlayer dielectric film, a contact hole, a contact plug and a nickel silicide film. The semiconductor substrate includes silicon. The interlayer dielectric film is formed on the semiconductor substrate. The contact hole is formed in the interlayer dielectric film. A contact plug is formed within the contact hole. A nickel silicide film is formed on a bottom part of the contact hole and electrically connected to the contact plug. A position of an interface between the nickel silicide and the contact plug is higher than a position of an interface between the semiconductor substrate and the interlayer dielectric film.

### First Embodiment

### (Method for Manufacturing Semiconductor Device)

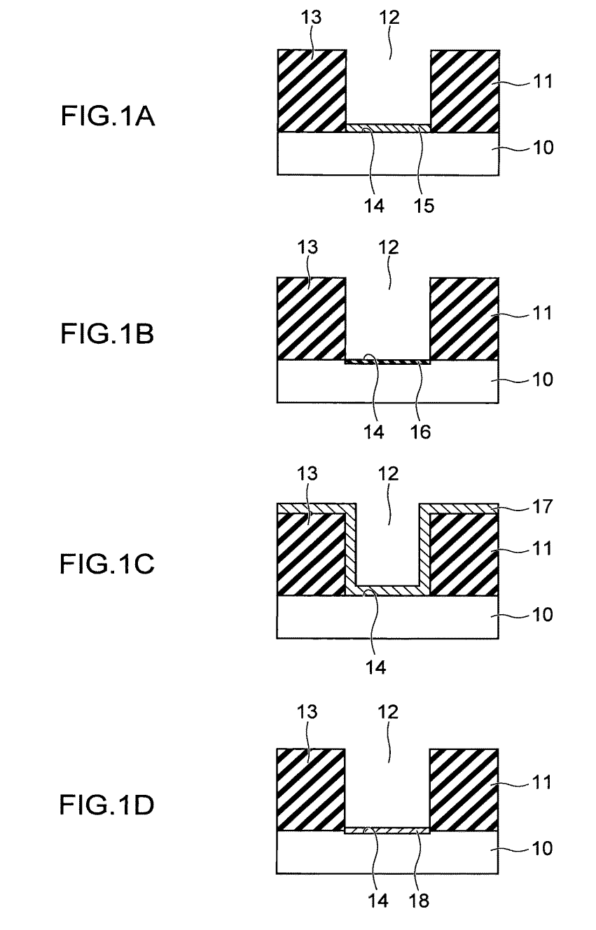

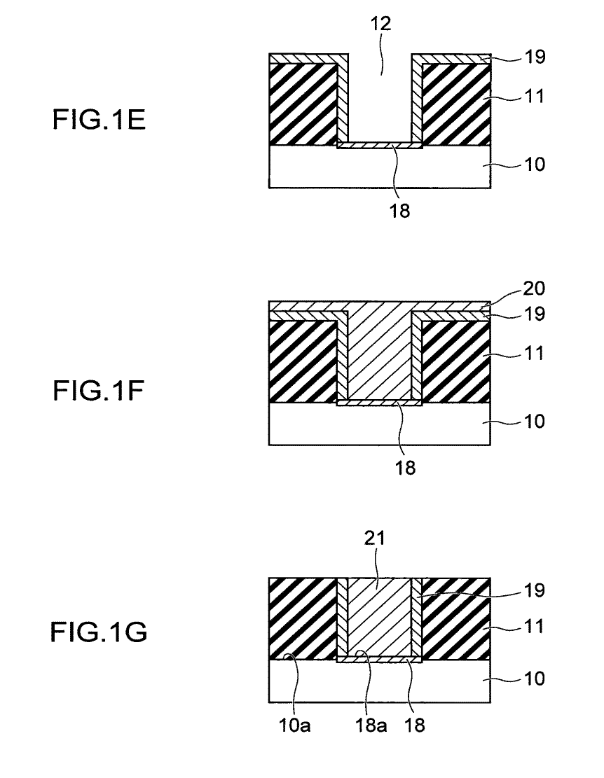

FIGS. 1A to 1G are main-part sectional views that show a manufacturing process of a semiconductor device of a first embodiment.

First, an interlayer dielectric film 11 is formed on a semiconductor substrate 10 by a CVD (Chmical Vapor Deposition) method.

The semiconductor substrate 10 contains silicon, polysilicon, or silicide. The semiconductor substrate 10 of the first embodiment is, for example, a silicon substrate. The semiconductor substrate 10 illustrated below is, for example, a section that includes a diffusion layer, and a contact plug described below is electrically connected to the diffusion layer.

The interlayer dielectric film 11 is, for example, silicon oxide (SiO₂). The silicon oxide is formed by, for example, the CVD method.

Next, a contact hole 12 is formed in the interlayer dielectric film 11 by a photolithography method and an RIE (Reactive Ion Etching) method as shown in FIG. 1A.

Next, a residue 15 remaining on a bottom part 14 of the contact hole 12 is removed. The residue 15 is a damaged layer of an underlying film formed, for example, while being etched or is a residual material that is generated while being etched. The residue 15 is removed by, for example, an oxygen ashing process.

Next, an oxide film 16 is formed on the bottom part 14 using a thermal oxidation method as shown in FIG. 1B. The oxide film 16 is, for example, silicon oxide. Then, the oxide film 16 is removed by a wet etching method. If the oxide film 16 on the bottom part 14 is not completely removed by the wet etching process, or if further oxide film is formed on the bottom part 14 by the wet etching process, all the oxide films are removed by a dry etching method.

Next, a nickel film 17 is formed on the side part 13 and bottom part 14 of the contact hole 12, and the interlayer dielectric film 11 by the CVD method as shown in FIG. 1C. The formation of the nickel film 17 is performed in the atmosphere of the mixed gas in which, for example, a nickel amid, hydrogen, and ammonia gas are mixed.

An impurity is also implanted into the nickel film 17 by ion implantation procedure. The impurity causes, for example, the upper temperature limit of the nickel film 17 to increase. The impurity is, for example, a nonmagnetic material or cobalt. In the embodiment, cobalt is used as an impurity. The upper temperature limit of the nickel film 17 is increased by the implantation of the impurity. The upper temperature limit of the nickel silicide film described below is thus increased (e.g., 700 to 800° C.), the nickel silicide film can withstand the high temperature when a conducting film described below is embedded.

Next, the nickel film 17 is silicidized using heat treatment. The heat treatment is performed, for example, at about 300° C. The heat treatment causes the upper part of the semiconductor substrate 10 and the nickel film 17 on the bottom part 14 of the contact hole 12 to be silicidized to form nickel silicide film 18 on the bottom part 14 of the contact hole 12.

Next, the nickel film 17 that remains without being silicidized is removed by the wet etching method as shown in FIG. 1D. The wet etching method causes the nickel silicide film 18 to be formed only on the bottom part 14 of the contact hole 12.

Next, barrier metal 19 is formed on the interlayer dielectric film 11 and on the side part 13 of the contact hole 12 by the CVD method as shown in FIG. 1E. The formation of the barrier metal 19 is performed, for example, at 650° C. or less. The barrier metal 19 is, for example, a titanium (Ti), titanium nitride (TiN), or multilayer film of titanium and titanium nitride (Ti/TiN). The barrier metal 19 is not formed on the exposed nickel silicide film 18 on the bottom part of the contact hole 12 due to the poor adhesion between the barrier metal 19 and the nickel silicide film 18.

Next, a conducting film 20 is embedded within the contact hole 12 by an ALD (Atomic Layer Deposion) method as shown in FIG. 1F.

The conducting film 20 is made up of, for example, a conducting material that is conductive, and includes tungsten, aluminum, or copper. The conducting film 20 of the embodiment is, for example, tungsten.

Next, the excess barrier metal 19 and conducting film 20 on the interlayer dielectric film 11 are removed to form a contact plug 21 by a CMP (Chemical Mechanical Polishing) method as shown in FIG. 1G. Then, the desired semiconductor device is achieved through a well-known process. The position of the interface 18a between the nickel silicide film 18 and the contact plug 21 is higher than the position of the interface 10a between the semiconductor substrate 10 and the interlayer dielectric film 11.

The formation of the nickel film 17 and nickel silicide film 18 is performed, for example, in the same chamber.

Alternatively, the formation may be performed in two separate chambers, respectively.

### (Effect of First Embodiment)

According to the first embodiment, after the contact hole 12 is formed, the nickel silicide film 18 is formed on its bottom part 14. Therefore, the influences of defects in a diffusion layer, making silicon polycrystalline, diffusion species, and the concentration of the diffusion species are small, and the contact resistance can be reduced.

### Second Embodiment

A second embodiment is different from the first embodiment in the way the further nickel silicide film is formed also on a side part of the interlayer dielectric film. In each embodiment below, the portion having the function and configuration similar to the first embodiment is assigned with the same reference character as the one assigned in the first embodiment, and the description of that portion will not be repeated.

A method for manufacturing a semiconductor device of the second embodiment will be explained below.

### (Method For Manufacturing Semiconductor Device)

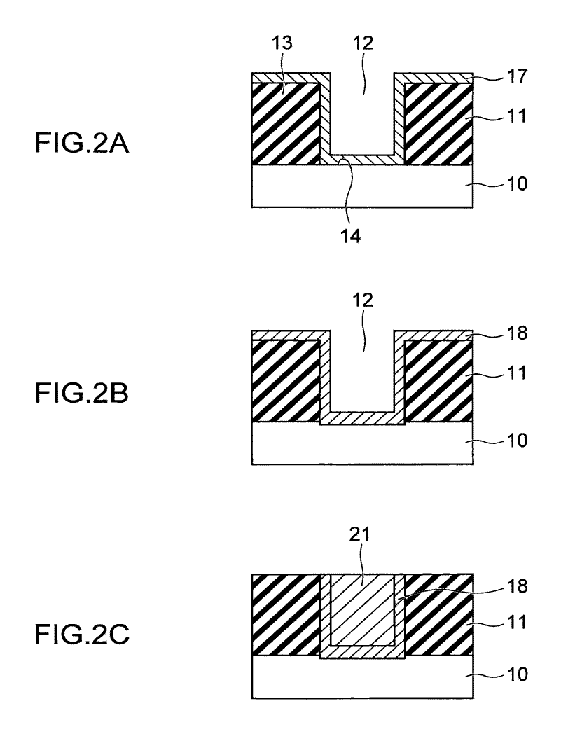

FIGS. 2A to C are main-part sectional views that show a manufacturing process of a semiconductor device of a second embodiment.

First, the interlayer dielectric film 11 is formed on a semiconductor substrate 10 by a CVD method. Then, a contact hole 12 is formed in an interlayer dielectric film 11 by a photolithography method and a RIE method. Then, as with the first embodiment, a residue remaining on a bottom part 14 is removed.

Next, a nickel film 17 is formed on a side part 13 and the bottom part 14 of the contact hole 12, and the interlayer dielectric film 11 by the CVD method as shown in FIG. 2A. Then, the impurity is implanted into the nickel film 17 by ion implantation procedure.

Next, a nickel silicide film 18 is formed on the side part 13 and the bottom part 14 of the contact hole 12, and the interlayer dielectric film 11 using heat treatment as shown in FIG. 2B.

The heat treatment is performed in the atmosphere of, for example, mono-silane (SiH₄) or disilane (Si₂H₆) at a temperature of 200° C. or more. The heat treatment causes silicon and the nickel film 17 contained in the atmosphere to be silicidized to convert not only the nickel film 17 on the bottom part 14 but also the nickel film 17 on interlayer dielectric film 11 and the side part 13 into a silicide. The heat treatment is performed, for example, in the same chamber as the one in which the nickel film 17 has been formed. Alternatively, the heat treatment may be performed in another chamber.

Next, a conducting film is embedded within the contact hole 12 by an ALD method. The process from the formation of the nickel silicide film 18 to the formation of the conducting film is performed, for example, in the same chamber. Alternatively, the process may be performed in separate chambers, respectively.

Next, the excess nickel silicide film 18 and conducting film on the interlayer dielectric film 11 are removed to form a contact plug 21 by a CMP method as shown in FIG. 2C. Then, the desired semiconductor device is achieved through a well-known process.

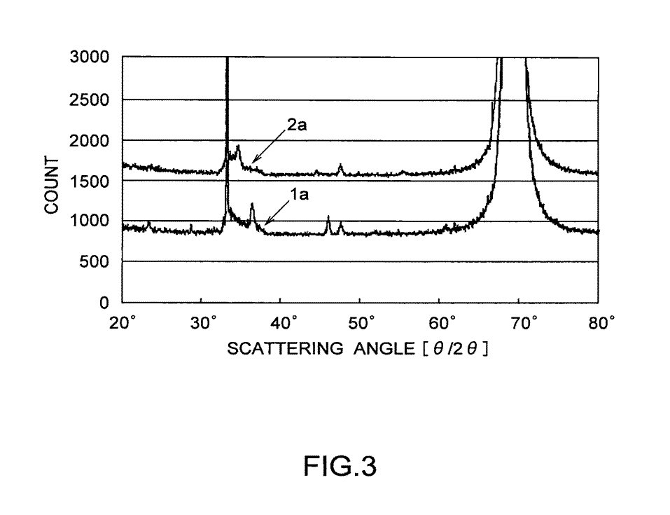

FIG. 3 is a graph that compares orientations of the nickel silicide films formed by using the manufacturing methods of the first and second embodiments. The graph shown in FIG. 3 is measured by an X-ray diffractometer using a θ/2θ method. The abscissa indicates the scattering angle (20° to 80°) of X rays, and the ordinate indicates the count (0 to 3000).

In the first embodiment, by performing the heat treatment after the nickel film 17 is formed, the nickel silicide film 18 is formed only on the portion (bottom part 14) that contacts the silicon of the semiconductor substrate 10. The first diffraction profile is shows the measurement result of the nickel silicide film 18 of the first embodiment.

On the other hand, in the second embodiment, by performing the heat treatment in the atmosphere of mono-silane or disilane under the condition of a temperature of 200° C. or more after the nickel film 17 is formed, the nickel silicide film 18 is formed on the side part 13 and the bottom part 14 of the contact hole 12, and the interlayer dielectric film 11. The second diffraction profile 2a shows the measurement result of the nickel silicide film 18 of the second embodiment.

As is clear from FIG. 3, it can be seen that the nickel silicide films formed by using the manufacturing methods of the first and second embodiments both show almost the same orientation. That is to say, both of the nickel silicide films formed by using the manufacturing methods of the first and second embodiments have the same characteristic, and the contact resistance can be reduced in the same way.

### (Contact Resistance)

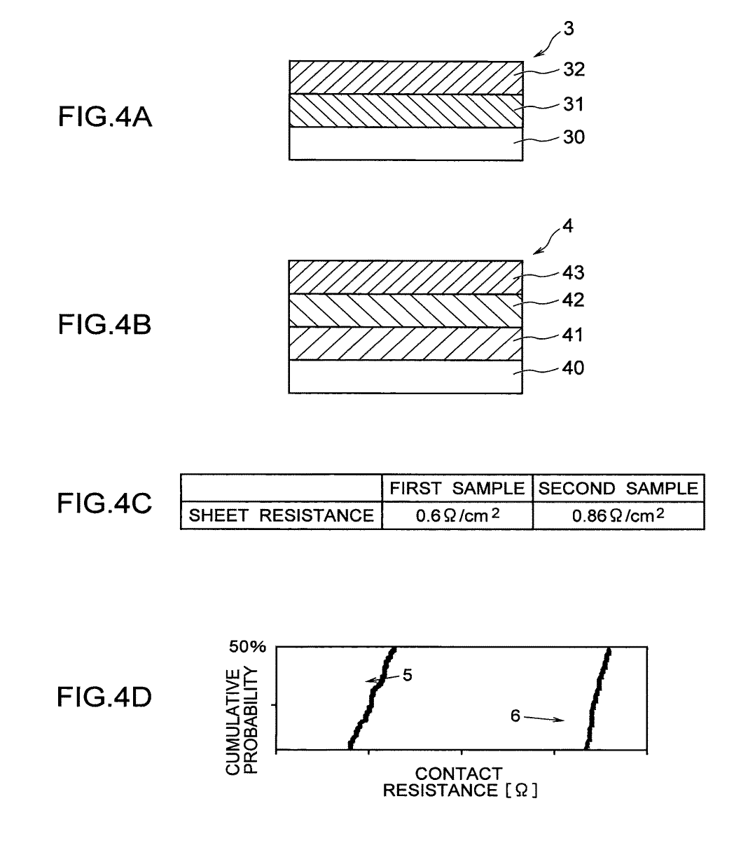

FIG. 4A is a main-part sectional view of a first sample of the second embodiment, FIG. 4B is a main-part sectional view of a second sample, FIG. 4C is a table that shows a sheet resistance (n) of the first and second samples, and FIG. 4D is a graph that shows the relationship between a contact resistance and cumulative probability of the first and second samples. A first sample 3 that has a configuration similar to the semiconductor device of the embodiment, and a sheet resistance and a contact resistance of a second sample 4 that has no nickel silicide film will be explained below.

In the first sample 3, a nickel silicide film 31, and a tungsten film 32 are formed on a silicon substrate 30 in series as shown in FIG. 4A.

In the second sample 4, a titanium film 41, a titanium nitride film 42, and a tungsten film 43 are formed on a silicon substrate 40 in series as shown in FIG. 4B. The titanium film 41 and the titanium nitride film 42 are barrier metals that prevent tungsten from diffusing. The silicon substrate 30 of the first sample 3 and silicon substrate 40 of the second sample 4 are intended to have the same thickness. The nickel silicide film 31, the tungsten film 32 and 43, the titanium film 41, and the titanium nitride film 42 are also intended to have the same thickness.

The sheet resistance of the first sample 3 and the second sample 4 described above was measured. The measurement result of the sheet resistance of the first sample 3 is a measurement result when the nickel silicide film 31 and the tungsten film 32 of the first sample 3 are formed in whole of a wafer. The measurement result of the sheet resistance of the second sample 4 is a measurement result when the titanium film 41, the titanium nitride film 42, and the tungsten film 43 of the second sample 4 are formed in whole of a wafer. The measurement results were that the sheet resistance of the first sample 3 was 0.6 Ω/cm², and the sheet resistance of the second sample 4 was 0.86 Ω/cm² as shown in FIG. 4C.

Each contact resistance was also measured (first profile 5) when a plurality of contact holes were formed in the interlayer dielectric film on the semiconductor substrate, and pieces of nickel silicide film were formed on the bottom parts of those contact holes. Each contact resistance was also measured (second profile 6) when pieces of barrier metal made up of the titanium silicide (TiSi₂) film, or the titanium (Ti) film/titanium nitride (TiN) film were formed on the bottom parts of the contact holes.

In FIG. 4D, the abscissa indicates the contact resistance, and the ordinate indicates at which percent of the entire contact the value of the contact resistance was measured (cumulative probability). It can be seen that the contact resistance in the case where the pieces of nickel silicide film are formed on the bottom parts is reduced to about ½ to 1/10 than that in the case where the pieces of the barrier metal made up of titanium silicide film, or titanium film/titanium nitride film are formed on the bottom parts as shown in FIG. 4D.

From the above result, it is understood that the contact resistance in the case where the nickel silicide film is formed on the bottom part of the contact hole is reduced than that in the case where the barrier metal made up of titanium silicide film, or titanium film/titanium nitride film is formed on the bottom part of the contact hole.

### (Effect of Second Embodiment)

According to the second embodiment, the nickel silicide film 18 is formed on the side part 13 of the contact hole 12 also. Therefore, the nickel silicide film 18 can be used as barrier metal as well. Further, according to the second embodiment, since the nickel silicide film 18 can be used as barrier metal as well, the contact resistance can be reduced than that in the case where the titanium/titanium nitride is used as barrier metal.

### Third Embodiment

A third embodiment is different from the other embodiments described above in the way the interlayer dielectric film has a layered structure in which a conducting film is formed that is electrically connected to the contact plug by the side part.

A method for manufacturing a semiconductor device of the present embodiment will be explained below.

### (Method for Manufacturing Semiconductor Device)

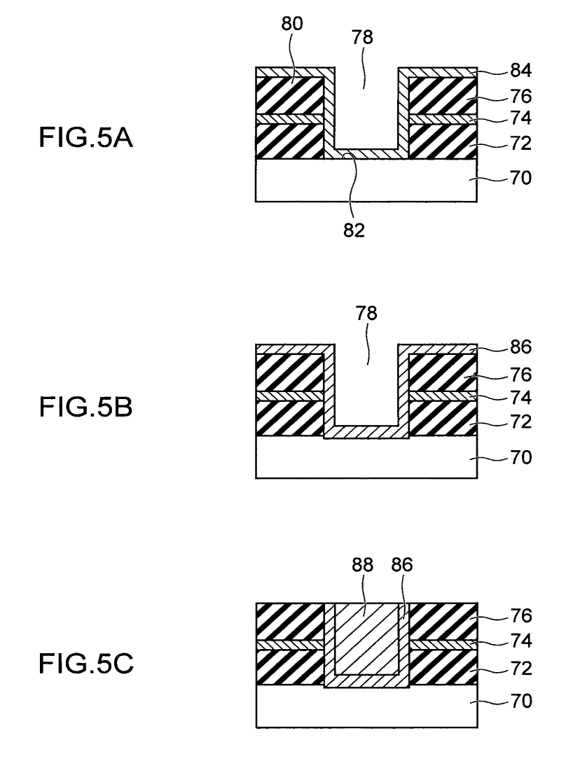

FIGS. 5A to 5C are main-part sectional views that show a manufacturing process of a semiconductor device of the third embodiment.

First, a first interlayer dielectric film 72 is formed on a semiconductor substrate 70 by a CVD method. Then, a conducting film 74 is formed on the first interlayer dielectric film 72 by the CVD method. The conducting film 74 is wiring made up of, for example, a conducting material. The conducting material is, for example, polysilicon, copper, or tungsten. In the third embodiment, the conducting film 74 is, for example, polysilicon. A plurality of conducting films 74 may be included within the first and a second interlayer dielectric films 72 and 76 and be exposed to a contact hole 78.

Next, the second interlayer dielectric film 76 is formed on the conducting film 74 by the CVD method. Then, the contact hole 78 that extends through the second interlayer dielectric film 76, the conducting film 74, and the first interlayer dielectric film 72 is formed by a photolithography method and a RIE method. Then, as with the first embodiment, a residue remaining on a bottom part 82 is removed. The first and second interlayer dielectric films 72 and 76 are, for example, silicon oxide.

Next, a nickel film 84 is formed on a side part 80 and the bottom part 82 of the contact hole 78, and the second interlayer dielectric film 76 by the CVD method as shown in FIG. 5A. Then, an impurity is implanted into the nickel film 84 by an ion implantation procedure.

Next, the nickel silicide film 86 is formed on the side part 80 and the bottom part 82 of the contact hole 78, and the second interlayer dielectric film 76 using heat treatment as shown in FIG. 5B. The heat treatment is performed, for example, under the same condition as the heat treatment in the second embodiment.

Next, the conducting film is embedded within the contact hole 78 by the ALD method.

Next, the excess nickel silicide film 86 and the conducting film on the second interlayer dielectric film 76 are removed to form a contact plug 88 by a CMP method as shown in FIG. 5C. Then, the desired semiconductor device is achieved through a well-known process.

### (Effect of Third Embodiment)

According to the third embodiment, the contact plug 88 connected electrically to the conducting film 74 exposed to the side part 80 of the contact hole 78 via the nickel silicide film 86 can be formed.

### (Effect of Embodiments)

According to the embodiments described above, after the contact hole is formed, the nickel silicide film is formed at least on its bottom part. Therefore, the influences of defects in a diffusion layer, making silicon polycrystalline, diffusion species, and the concentration of the diffusion species are small, and the contact resistance can be reduced.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a semiconductor substrate comprising silicon;
an interlayer dielectric film on the semiconductor substrate;
a contact hole in the interlayer dielectric film;
a contact plug within the contact hole; and
a nickel silicide film on a bottom part of the contact hole and electrically connected to the contact plug,
wherein a position of an interface between the nickel silicide and the contact plug is higher than a position of an interface between the semiconductor substrate and the interlayer dielectric film.

2. The semiconductor device of claim 1, wherein the nickel silicide film is further formed on a side part of the contact hole.

3. The semiconductor device of claim 2, further comprising a conducting film electrically connected to the nickel silicide film,
wherein the interlayer dielectric film comprises a first interlayer dielectric film under the conducting film and a second interlayer dielectric film on the conducting film.

4. A method for manufacturing a semiconductor device, the method comprising:
forming an interlayer dielectric film on a semiconductor substrate comprising silicon;
forming a contact hole in the interlayer dielectric film;
forming a nickel film on a side part and a bottom part of the contact hole;
performing heat treatment to cause an upper part of the semiconductor substrate and the bottom part to be silicidized to form a nickel silicide film on the bottom part of the contact hole; and
embedding a conducting material into the contact hole to form a contact plug.

5. The method of claim 4, further comprising implanting an impurity into the nickel film,
wherein the heat treatment is performed after implanting the impurity.

6. The method of claim 4, further comprising removing the nickel film which remains without being silicidized in the heat treatment.

7. The method of claim 6, wherein in removing the nickel film, the nickel film is removed by a wet etching method.

8. The method of claim 4, further comprising forming barrier metal on the interlayer dielectric film and on the side part of the contact hole.

9. The method of claim 4, wherein in forming the nickel silicide film, the heat treatment is performed in an atmosphere of gas comprising the silicon to form the nickel silicide film on the bottom part and the side part of the contact hole, the heat treatment causing the gas and the nickel film to be silicidized.

10. The method of claim 9, wherein in forming the nickel silicide film, the nickel silicide film is formed further on the interlayer dielectric film.

11. The method of claim 9, further comprising implanting an impurity into the nickel film, wherein the heat treatment is performed after implanting the impurity.

12. The method of claim 9, further comprising removing the nickel film which remains without being silicidized in the heat treatment.

13. The method of claim 9, wherein in removing the nickel film, the nickel film is removed by a wet etching method.

14. The method of claim 9, further comprising forming barrier metal on the interlayer dielectric film and on the side part of the contact hole.

15. The method of claim 9, wherein in forming the interlayer dielectric film, a first interlayer dielectric film is formed on the semiconductor substrate, a conducting film electrically connected to the nickel silicide film is formed, and a second interlayer dielectric film is formed on the conducting film.

16. The method of claim 15, wherein in forming the interlayer dielectric film, the interlayer dielectric film is formed further on the second interlayer dielectric film.

17. The method of claim 15, further comprising implanting an impurity into the nickel film,
wherein the heat treatment is performed after implanting the impurity.

18. The method of claim 15, further comprising removing the nickel film which remains without being silicidized in the heat treatment.

19. The method of claim 15, wherein in removing the nickel film, the nickel film is removed by a wet etching method.

20. The method of claim 15, further comprising forming barrier metal on the interlayer dielectric film and on the side part of the contact hole.
